(19) United States
(12) Patent Application Publication
(10) Pub. No.: US 2025/0035564 A1
(43) Pub. Date: Jan. 30, 2025

(54) SUBSTRATE TEST METHOD

(71) Applicant: SAMSUNG ELECTRONICS CO., LTD., Suwon-si (KR)

(72) Inventors: Sung-Il Choi, Suwon-si (KR); Byeongkwan Song, Suwon-si (KR); Chulmoo Kang, Suwon-si (KR); Kang-Woong Ko, Suwon-si (KR); Kyungbeom Kim, Suwon-si (KR); Mira Park, Suwon-si (KR); Yongseok Won, Suwon-si (KR); Younsub Lee, Suwon-si (KR); Jeonghoo Jo, Suwon-si (KR)

(21) Appl. No.: 18/441,476

(22) Filed: Feb. 14, 2024

(30) Foreign Application Priority Data
Jul. 24, 2023 (KR) 10-2023-0096329

(51) Int. Cl. H01L 21/66; G06T 7/00; G06T 7/13

(52) U.S. Cl. CPC G01N 21/9503; G06T 7/0004; G06T 7/13; H01L 21/67288

(57) ABSTRACT

The present disclosure relates to substrate test methods. An example substrate test method comprises loading a substrate into a substrate test apparatus and testing the substrate in the substrate test apparatus. The step of testing the substrate includes testing a first region of the substrate, and testing a second region of the substrate after testing the first region. The step of testing the first region includes determining that the first region is aligned and irradiating light to the first region. The step of testing the second region includes determining that the second region is aligned and irradiating light to the second region.

### CROSS-REFERENCE TO RELATED APPLICATION

This application claims priority under 35 U.S.C § 119 to Korean Patent Application No. 10-2023-0096329 filed on Jul. 24, 2023 in the Korean Intellectual Property Office, the disclosure of which is hereby incorporated by reference in its entirety.

### BACKGROUND

A semiconductor device may be fabricated through various processes. For example, the semiconductor device may be manufactured through a photolithography process, an etching process, a deposition process, a plating process, and a test process that performed on a substrate. Many regions on a substrate may be tested in a substrate test process. For example, it is possible to test two or more regions spaced apart from each other on the substrate. After one region is tested, the substrate may move.

### SUMMARY

The present disclosure relates to substrate test methods, including a substrate test method capable of exactly ascertaining a substrate alignment state, a substrate test method capable of achieving an accurate test, and a substrate test method capable of accomplishing a prompt test.

The object of the present disclosure is not limited to the mentioned above, and other objects which have not been mentioned above will be clearly understood to those skilled in the art from the following description.

In general, according to some aspects, a substrate test method comprises: loading a substrate into a substrate test apparatus; and testing the substrate in the substrate test apparatus. The step of testing the substrate includes: testing a first region of the substrate; and testing a second region of the substrate after testing the first region, the second region being spaced apart from the first region. The step of testing the first region includes: ascertaining an alignment of the first region; and irradiating light to the first region. The step of testing the second region includes: ascertaining an alignment of the second region; and irradiating light to the second region.

In general, according to some aspects, a substrate test method comprises: using an optical irradiation device to irradiate light to a first cell of a substrate; receiving light reflected from the first cell; moving the substrate after receiving the light reflected from the first cell; ascertaining an alignment of the substrate after moving the substrate; using the optical irradiation device to irradiate light to a second cell of the substrate; and receiving light reflected from the second cell.

In general, according to some aspects, a substrate test method comprises: testing a first region of a substrate; and testing a second region of the substrate. The step of testing the first region includes: irradiating light to the first region; and receiving light reflected from the first region. The step of testing the second region includes: ascertaining an alignment of the second region spaced apart from the first region; irradiating light to the second region; and receiving light reflected from the second region.

Details of other example implementations are included in the description and drawings.

### BRIEF DESCRIPTION OF THE DRAWINGS

FIG. 1 illustrates a cross-sectional view showing an example of a substrate test apparatus.

FIG. 2 illustrates a flow chart showing an example of a substrate test method.

FIGS. 3 to 12 illustrate example diagrams showing a substrate test method according to the flow chart of FIG. 2.

### DETAILED DESCRIPTION

The following will now describe some implementations of the present disclosure with reference to the accompanying drawings. Like reference numerals may indicate like components throughout the description.

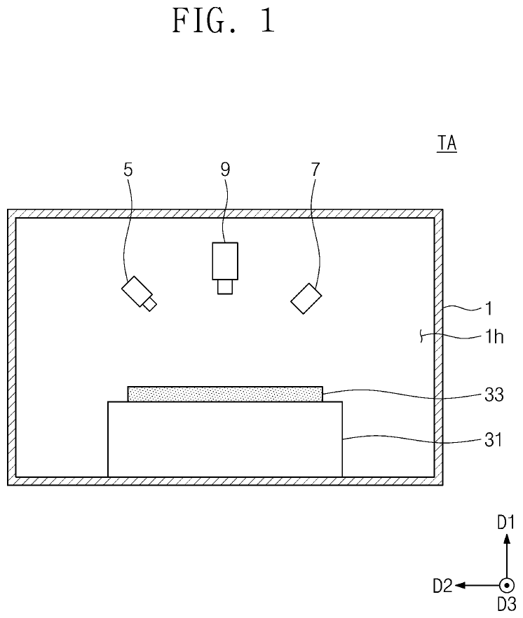

FIG. 1 illustrates a cross-sectional view showing an example of a substrate test apparatus.

Referring to FIG. 1, a substrate test apparatus TA is provided. The substrate test apparatus TA tests a substrate. A term “substrate” used in this description may denote a silicon (Si) wafer, but the present disclosure are not limited thereto. The substrate test apparatus TA performs, for example, spectroscopic ellipsometry on a substrate. For example, the substrate test apparatus TA performs an optical critical dimension (OCD) measurement on a substrate. The substrate test apparatus TA is an OCD measurement device. The present disclosure, however, are not limited thereto, and the substrate test apparatus TA may perform other test processes on a substrate. The substrate test apparatus TA includes a test chamber 1, a stage 31, a chuck 33, an optical irradiation device 5, a detector 7, and an optical camera 9.

The test chamber 1 may provide a test space 1h. A substrate test may be performed in a state where a substrate is disposed in the test space 1h.

The stage 31 may be positioned in the test chamber 1. A substrate loaded in the test space 1h may be disposed on the stage 31. The stage 31 may move a substrate. A detailed description thereof will be further discussed below.

The chuck 33 may be positioned on the stage 31. The chuck 33 may hold a substrate. For example, a substrate may be held on a certain position on the chuck 33. The chuck 33 may include various configurations for holding a substrate. For example, the chuck 33 may include a vacuum chuck. The present disclosure, however, are not limited thereto, and the chuck 33 may be an electrostatic chuck (ESC). The chuck 33 may be movable. For example, the stage 31 may drive the chuck 33 to move in a horizontal direction. Thus, the stage 31 may move the chuck 33. Therefore, a substrate on the chuck 33 may move in a horizontal direction.

The optical irradiation device 5 may be positioned in the test chamber 1. The optical irradiation device 5 may irradiate light toward the chuck 33. For example, the optical irradiation device 5 may irradiate light to a top surface of a substrate on the chuck 33. A detailed description thereof will be further discussed below.

The detector 7 may be positioned in the test chamber 1. The detector 7 may receive light. For example, the detector 7 may receive light that is emitted from the optical irradiation device 5 and reflected from a substrate on the chuck 33. A detailed description thereof will be further discussed below.

The optical camera 9 may be positioned in the test chamber 1. The optical camera 9 may be disposed at a location upwardly spaced apart from the chuck 33. The optical camera 9 may be capture a substrate on the chuck 33. The optical camera 9 may obtain an optical image of a specific region on a substrate. A detailed description thereof will be further discussed below.

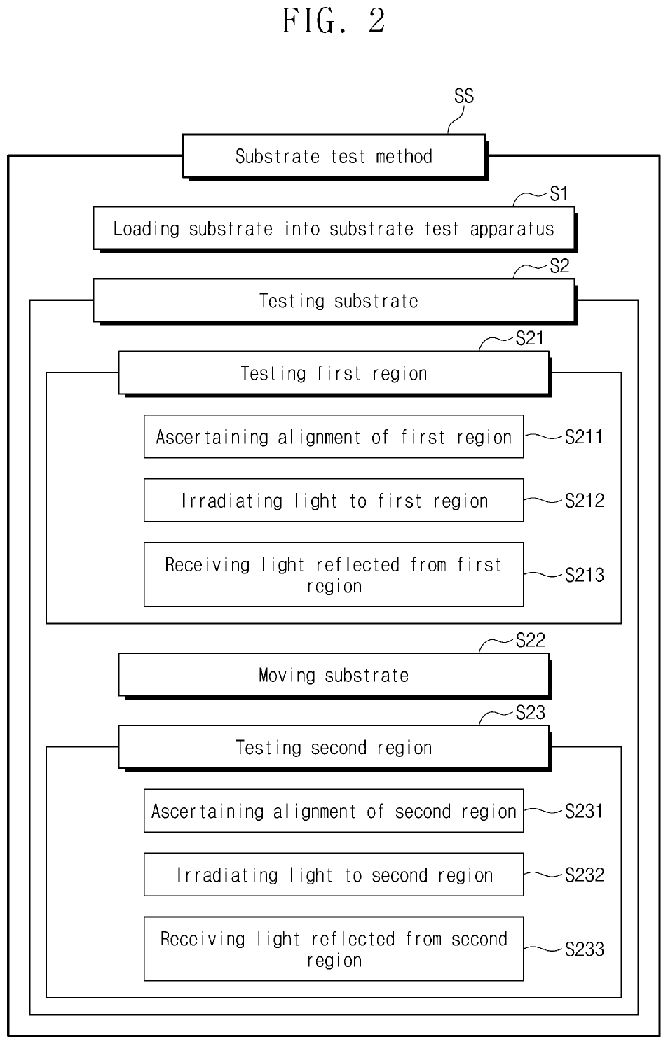

FIG. 2 illustrates a flow chart showing an example of a substrate test method.

Referring to FIG. 2, a substrate test method SS is provided. The substrate test method SS is a method in which the substrate test apparatus TA discussed with reference to FIG. 1 is used to test a substrate. The substrate test method SS includes loading a substrate into a substrate test apparatus (S1) and testing the substrate (S2).

The step S2 includes testing a first region (S21), moving the substrate (S22), and testing a second region (S23).

The step S21 includes ascertaining an alignment of the first region (S211), irradiating light to the first region (S212), and receiving light reflected from the first region (S213).

The step S23 includes ascertaining an alignment of the second region (S231), irradiating light to the second region (S232), and receiving light reflected from the second region (S233).

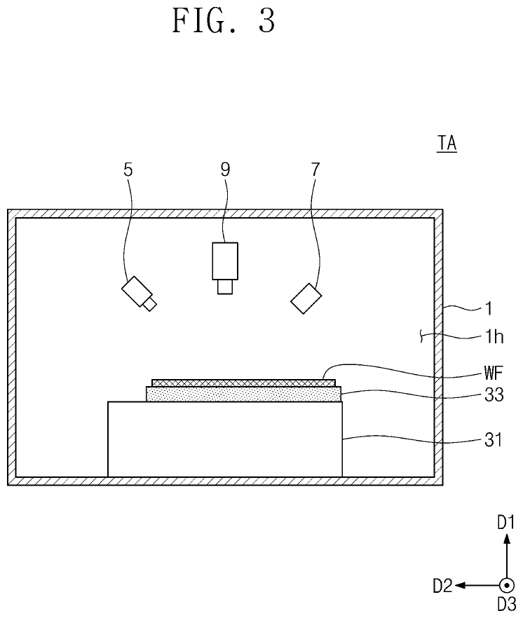

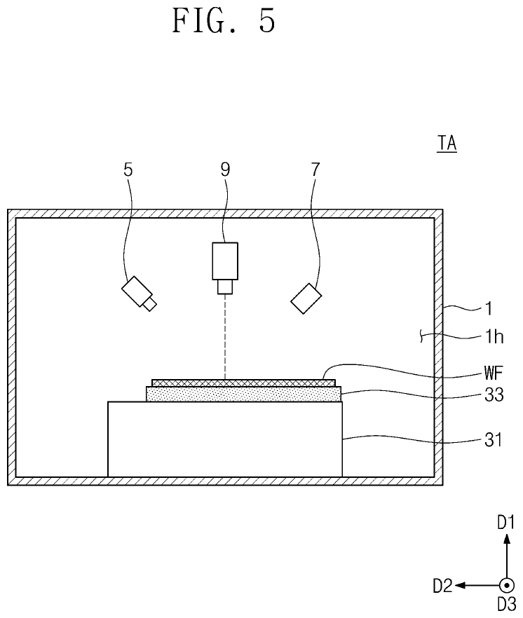

With reference to FIGS. 3 to 12, the following describe in detail the substrate test method SS of FIG. 2.

FIGS. 3 to 12 illustrate example diagrams showing a substrate test method according to the flow chart of FIG. 2.

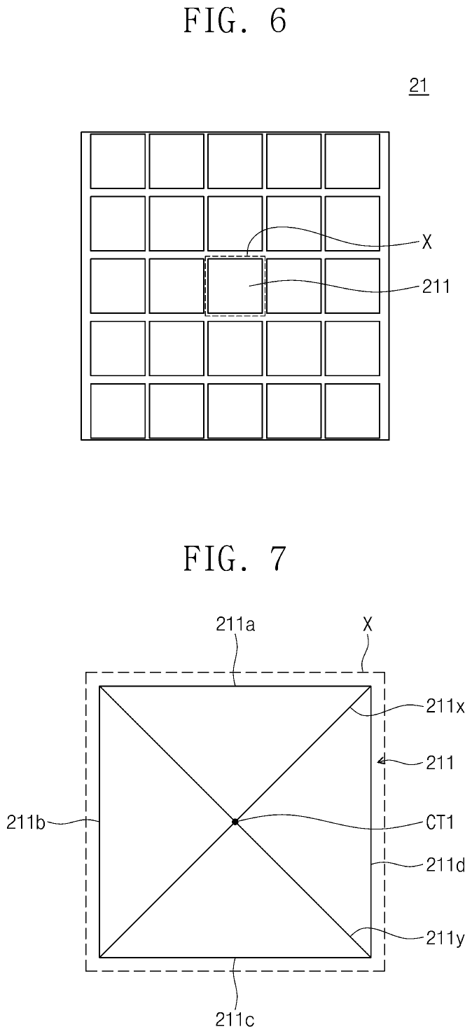

Referring to FIGS. 2 and 3, the step S1 may include placing a substrate WF on the stage 31. For example, the wafer WF may be disposed on the chuck 33. The chuck 33 may hold the wafer WF to a certain position. For example, the chuck 33 may use a vacuum pressure to hold the wafer WF to a certain position. Alternatively, the chuck 33 may use an electrostatic force to hold the wafer WF to a certain position. In this procedure, the wafer WF may be disposed to allow the optical irradiation device 5 and/or the optical camera 9 to face a first region (see 211 of FIG. 6). A detailed description thereof will be further discussed below.

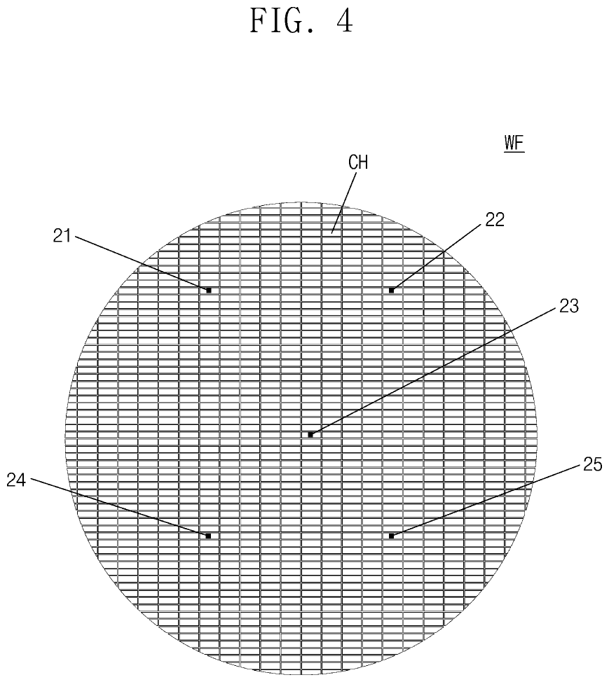

Referring to FIG. 4, the wafer WF may include a plurality of chips CH. One of the plurality of chips CH may be divided into a plurality of regions. For example, the wafer WF may include a plurality of regions. The substrate test apparatus (see TA of FIG. 1) may perform a test on the plurality of regions on the substrate WF. For example, the substrate test apparatus TA may perform a test on five of the plurality of regions on the substrate WF. The five regions may be disposed spaced apart from each other. The five regions may be correspondingly positioned in five chips CH. The test-target five chips CH may be called a first chip 21, a second chip 22, a third chip 23, a fourth chip 24, and a fifth chip 25.

Referring to FIGS. 2, 5, and 6, the step S211 may be performed by the optical camera 9. In the step S211, the substrate WF may be disposed to allow the optical camera 9 to face a first region 211. Thus, the first region 211 may be captured in a state where the placement of the optical camera 9 is not changed. The optical camera 9 may obtain a first image of the first region 211. The first region 211 may be a portion of the first chip (see 21 of FIG. 4). For example, the first region 211 may be one cell in the first chip 21. The step S211 may include ascertaining whether the first region 211 is positioned at an allowable location in the first image.

Referring to FIG. 7, the first image of the first region (see 211 of FIG. 6) may be provided. For example, an image of FIG. 7 may be the first image. The step of ascertaining whether the first region 211 is positioned at an allowable location may be performed by using a position of an edge line of the first region 211. For example, when the first region 211 has a rectangular shape as shown in FIG. 7, the edge line of the first region 211 may include a first edge line 211a, a second edge line 211b, a third edge line 211c, and a fourth edge line 211d. Positions of the four edge lines may be used to ascertain whether the first region 211 is positioned at the allowable location in the first image. Alternatively, the step of ascertaining whether the first region 211 is positioned at an allowable location may be performed by using a position of a first center CT1 of the first region 211. The first center CT1 of the first region 211 may be, for example, an intersection point of two diagonal lines 211x and 211y on the first region 211. A detailed description thereof will be further discussed below.

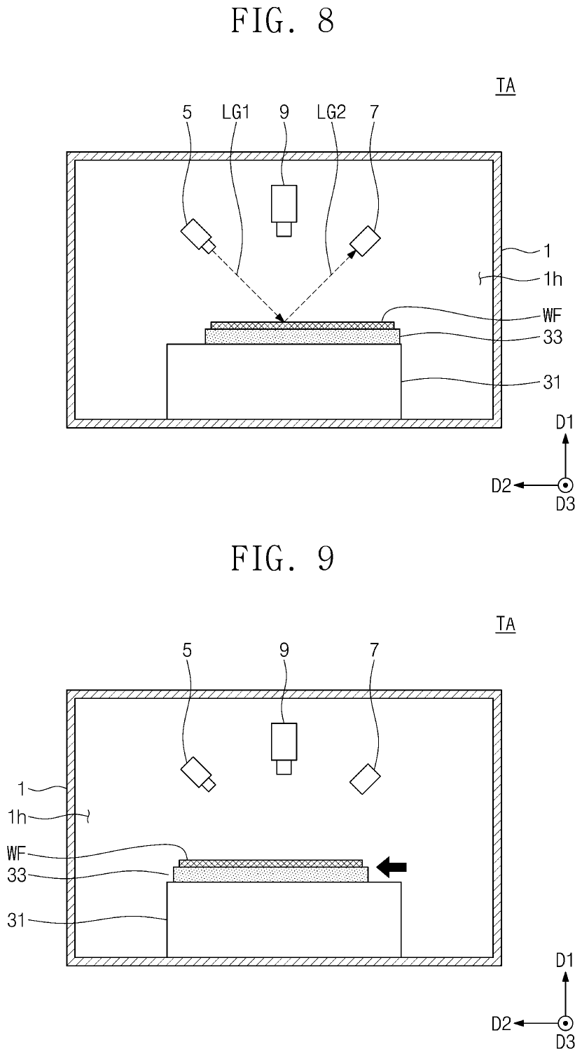

Referring back to FIGS. 2 and 8, the step S21 may further include using the optical camera 9 to ascertain a position of the first region (see 211 of FIG. 6) in the wafer WF. For example, the optical camera 9 may not only ascertain an alignment state of the first region 211, but identify where the first region 211 is located in the wafer WF.

Referring to FIGS. 2 and 8, the step S212 may be performed by the optical irradiation device 5. The optical irradiation device 5 may irradiate light LG1 to the first region (see 211 of FIG. 6) of the wafer WF. In this procedure, the substrate WF may be disposed to allow the optical irradiation device 5 to face the first region 211 of the wafer WF. Therefore, the light LG1 may be irradiated to the first region 211 in a state where the placement of the optical irradiation device 5 is not changed.

The step S213 may be performed by the detector 7. The detector 7 may receive light LG2 reflected from the substrate WF. For example, the detector 7 may receive the light LG2 that is emitted from the optical irradiation device 5 and reflected from the first region (see 211 of FIG. 6). Based on information received by the detector 7, measurement of the first region 211 may be performed. It may thus be possible to ascertain whether the first region 211 is defective.

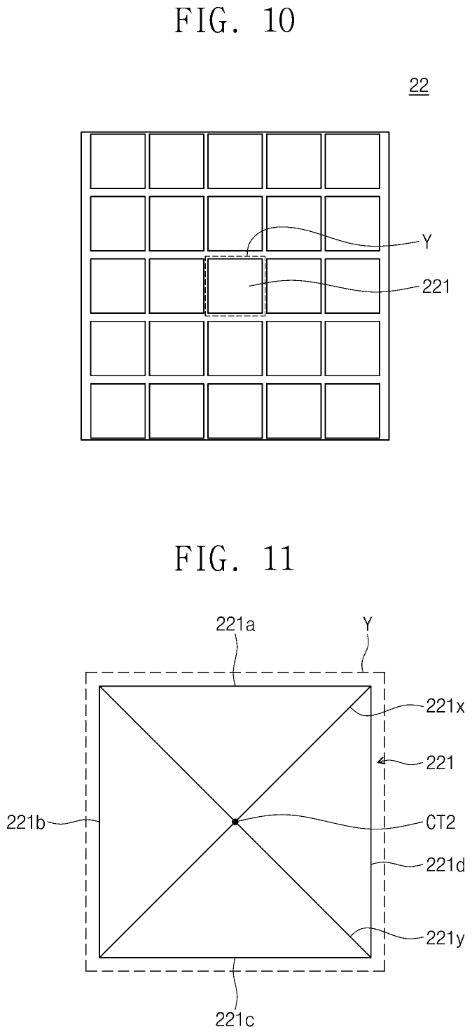

Referring to FIGS. 2 and 9, the step S22 may be preceded by the step S21. The step S22 may include moving the wafer WF to allow the optical irradiation device 5 and/or the optical camera 9 to face a second region (see 221 of FIG. 10). The step S22 may be performed by the stage 31. For example, in a state where the wafer WF is held on the chuck 33, the stage 31 may drive the chuck 33 to move in a horizontal direction. Therefore, the wafer WF held on the chuck 33 may move.

Referring to FIGS. 2 and 10, the step S231 may be performed by the optical camera 9. In the step S231, the substrate WF may be disposed to allow the optical camera 9 to face the second region 221. Thus, the second region 221 may be captured in a state where the placement of the optical camera 9 is not changed. The optical camera 9 may obtain a second image of the second region 221. The second region 221 may be a portion of the second chip (see 22 of FIG. 4). For example, the second region 221 may be one cell in the second chip 22. The step S231 may include ascertaining whether the second region 221 is positioned at an allowable location in the second image.

Referring to FIG. 11, a second image of the second region (see 221 of FIG. 10) may be provided. For example, an image of FIG. 11 may be the second image. The step of ascertaining whether the second region 221 is positioned at an allowable location may be performed by using a position of an edge line of the second region 221. For example, when the second region 221 has a rectangular shape as shown in FIG. 11, the edge line of the second region 221 may include a first edge line 221a, a second edge line 221b, a third edge line 221c, and a fourth edge line 221d. Positions of the four edge lines may be used to ascertain whether the second region 221 is positioned at the allowable location in the second image. Alternatively, the step of ascertaining whether the second region 221 is positioned at the allowable location in the second image may be performed by using a position of a second center CT2 of the second region 221. The second center CT2 of the second region 221 may be, for example, an intersection point of two diagonal lines 221x and 221y on the second region 221.

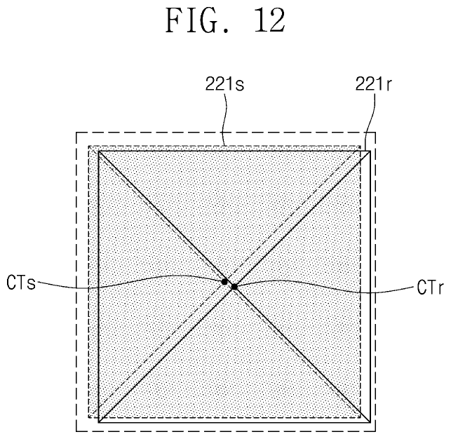

Referring to FIGS. 11 and 12, an image may be provided which shows an actual location 221r and an allowable location 221s of the second region 221. An allowable center CTs may be defined to indicate a center of the allowable location 221s of the second region 221. An actual center CTr may be defined to indicate a center of the actual location 221r of the second region 221. A difference in location between the allowable center CTs and the actual center CTr may be used to determine whether the second region 221 is positioned at the allowable location 221s.

When the second region 221 is not positioned in the allowable location 221s, the wafer (see WF of FIG. 9) may move again. The wafer WF may move until the second region 221 is positioned in the allowable location 221s. Alternatively, when the second region 221 is not positioned in the allowable location 221s, the substrate test apparatus (see TA of FIG. 9) may undergo maintenance. For example, when the second region 221 is not positioned in the allowable location 221s, a test of the wafer WF may stop, and the substrate test apparatus TA may experience maintenance.

Referring back to FIGS. 2 and 8, the step S232 may be performed by the optical irradiation device 5. The optical irradiation device 5 may irradiate the light LG1 to the second region (see 221 of FIG. 10) of the wafer WF. In this procedure, the substrate WF may be disposed to allow the optical irradiation device 5 to face the second region 221 of the wafer WF. Therefore, the light LG1 may be irradiated to the second region 221 in a state where the placement of the optical irradiation device 5 is not changed.

The step S233 may be performed by the detector 7. The detector 7 may receive the light LG2 reflected from the substrate WF. For example, the detector 7 may receive the light LG2 that is emitted from the optical irradiation device 5 and reflected from the second region (see 221 of FIG. 10). Based on information received by the detector 7, measurement of the second region 221 may be performed. It may thus be possible to ascertain whether the second region 221 is defective.

Referring back to FIG. 2, the substrate test method SS may further include testing a third region. The third region may be a portion of the third chip (see 23 of FIG. 4). For example, the third region may be one cell in the third chip 23. The step of testing a third region may include ascertaining an alignment of the third region, irradiating light to the third region, and receiving light reflected from the third region. The step of ascertaining an alignment of the third region, the step of irradiating light to the third region, and the step of receiving light reflected from the third region may be substantially the same as or similar to the step of ascertaining an alignment of the first region, the step of irradiating light to the first region, and the step of receiving light reflected from the first region, respectively.

It is illustrated that three regions are tested, but the present disclosure are not limited thereto. For example, fourth or more regions may be tested.

According to a substrate test method in accordance with some implementations of the present disclosure, it may be possible to exactly ascertain an alignment state of a substrate. For example, before each region is tested, it may be possible to independently ascertain an alignment state of each region. Therefore, even when the substrate experiences deformation such as warpage, each region may be exactly tested.

According to a substrate test method in accordance with some implementations of the present disclosure, an alignment state of a substrate may be ascertained again after movement of the substrate. Therefore, when the substrate experiences deformation or misalignment during movement of the substrate, the deformation or misalignment may be detected.

According to a substrate test method in accordance with some implementations of the disclosure, when a substrate is misaligned, the misalignment may be detected in advance to correct a position of the substrate. It may thus be possible to perform a prompt test.

According to a substrate test method in accordance with some implementations of the present disclosure, an optical camera may be used to ascertain alignment of a substrate. Thus, the alignment of the substrate may be ascertained without introducing an additional apparatus for ascertaining the alignment of the substrate. Accordingly, costs may be reduced, and a prompt test may be performed.

According to a substrate test method of the present disclosure, it may be possible to exactly ascertain an alignment state of a substrate.

According to a substrate test method of the present disclosure, it may be possible to perform an accurate test.

According to a substrate test method of the present disclosure, it may be possible to execute a prompt test.

Effects of the present disclosure are not limited to the mentioned above, other effects which have not been mentioned above will be clearly understood to those skilled in the art from the following description.

While this specification contains many specific implementation details, these should not be construed as limitations on the scope of any invention or on the scope of what may be claimed, but rather as descriptions of features that may be specific to particular implementations of particular inventions. Certain features that are described in this specification in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations and even initially be claimed as such, one or more features from a claimed combination can in some cases be excised from the combination, and the claimed combination may be directed to a subcombination or variation of a subcombination.

Although the concepts described herein have been described in connection with some implementations of the present disclosure illustrated in the accompanying drawings, it will be understood to those skilled in the art that various changes and modifications may be made without departing from the technical spirit and essential feature of the present disclosure. It therefore will be understood that the implementations described above are just illustrative but not limitative in all aspects.

What is claimed is:

1. A substrate test method, comprising:
loading a substrate into a substrate test apparatus; and
testing the substrate in the substrate test apparatus,
wherein testing the substrate includes:
testing a first region of the substrate; and
testing a second region of the substrate after testing the first region, the second region being spaced apart from the first region,
wherein testing the first region includes:
determining that the first region is aligned; and
irradiating light to the first region, and
wherein testing the second region includes:
determining that the second region is aligned; and
irradiating light to the second region.

2. The substrate test method of claim 1, wherein determining that the first region is aligned is performed by an optical camera.

3. The substrate test method of claim 2, wherein determining that the first region is aligned includes:
allowing the optical camera to obtain a first image of the first region; and
determining whether the first region is positioned at an allowable location in the first image.

4. The substrate test method of claim 3, wherein determining whether the first region is positioned at the allowable location is based on a position of an edge line of the first region.

5. The substrate test method of claim 3, comprising maintaining the substrate test apparatus when the first region is positioned at the allowable location.

6. The substrate test method of claim 2, wherein testing the first region includes allowing the optical camera to determine a position of the first region in the substrate.

7. The substrate test method of claim 1, wherein testing the first region includes receiving light reflected from the first region.

8. The substrate test method of claim 1, wherein, after testing the first region of the substrate and before testing the second region of the substrate, testing the substrate includes moving the substrate.

9. The substrate test method of claim 8, wherein testing the first region of the substrate and testing the second region of the substrate are performed by an optical irradiation device,
wherein, when the first region of the substrate is tested, the substrate is disposed to allow the optical irradiation device to face the first region, and
wherein moving the substrate includes allowing the optical irradiation device to face the second region.

10. The substrate test method of claim 1, comprising testing a third region of the substrate after testing the second region, the third region being spaced apart from the second region,
wherein testing the third region includes:
determining that the third region is aligned; and
irradiating light to the third region.

11. A substrate test method, comprising:
irradiating light to a first cell of a substrate by using an optical irradiation device;
receiving light reflected from the first cell;
moving the substrate after receiving the light reflected from the first cell;
determining that the substrate is aligned after moving the substrate;
irradiating light to a second cell of the substrate by using the optical irradiation device; and
receiving light reflected from the second cell.

12. The substrate test method of claim 11, wherein determining that the substrate is aligned includes obtaining an image of the second cell by using an optical camera.

13. The substrate test method of claim 12, wherein determining that the substrate is aligned includes:
determining an edge line of the second cell in the image; and
determining whether the second cell is positioned at an allowable location based on the edge line.

14. The substrate test method of claim 13, wherein determining that the substrate is aligned includes determining a position of a center of the second cell based on the edge line.

15. The substrate test method of claim 13, wherein determining that the substrate is aligned includes moving the substrate again when the second cell is not positioned in the allowable location.

16. The substrate test method of claim 11, comprising:
determining whether the first cell is defective based on a first data about the light reflected from the first cell; and
determining whether the second cell is defective based on a second data about the light reflected from the second cell.

17. A substrate test method, comprising:
testing a first region of a substrate; and
testing a second region of the substrate,
wherein testing the first region includes:
irradiating light to the first region; and
receiving light reflected from the first region, and
wherein testing the second region includes:
determining that the second region is aligned, the second region being spaced apart from the first region;
irradiating light to the second region; and
receiving light reflected from the second region.

18. The substrate test method of claim 17, wherein determining that the second region is aligned includes:
obtaining an image of the second region; and
determining whether the second region is positioned at an allowable location in the image.

19. The substrate test method of claim 18, comprising alarming when the second region is not positioned at the allowable location.

20. The substrate test method of claim 17, after testing the first region and before testing the second region, the substrate test method comprising moving the substrate.
